(19) United States
(12) Patent Application Publication
(10) Pub. No.: US 2024/0020429 A1
(43) Pub. Date: Jan. 18, 2024

(54) Subsea Nodes With Embedded Sensors

(71) Applicant: Stress Engineering Services, Inc., Houston, TX (US)

(72) Inventors: Patrick Boster, The Woodlands, TX (US); Matthew Wayne Sanders, Cypress, TX (US); William Paul Walker, Tomball, TX (US)

(73) Assignee: Stress Engineering Services, Inc., Houston, TX (US)

(21) Appl. No.: 18/351,336

(22) Filed: Jul. 12, 2023

Related U.S. Application Data
(60) Provisional application No. 63/368,244, filed on Jul. 12, 2022.

(51) Int. Cl. G06F 30/10; B33Y 80/00; B33Y 10/00

(52) U.S. Cl. CPC G06F 30/10; B33Y 80/00; B33Y 10/00

(57) ABSTRACT

A method and apparatus for forming a sensor within a subsea node using additive manufacturing.

### RELATED APPLICATIONS

This application claims priority to U.S. Provisional Application No. 63/368,244, filed Jul. 12, 2022.

### BACKGROUND OF THE INVENTION

Generally, vibration-induced fatigue damage and strain induced from other sources is a problem in various structures, including fixed bottom jacket structures, and floating structures, which are used in offshore wind applications and similar structures. These structures are fabricated with metallic tubular members. However, measurement or estimation of the structure fatigue damage at nodal intersections has been difficult or impossible to measure, due to the nature of the structure node locations underwater in the offshore environment in which they are used.

Previous basis for design method involved use of preexisting dated industry codes and standards and periodic monitoring of the critical nodal intersections. Embedded sensors gather critical insitu data useful to validate design models as well as assessing structural damage due to the unpredictable nature of the offshore environment. For example, utilizing data from an upper and lower tubular member connection, respectively, providing dynamic motion and orientation data of the two ends of the connecting branch or chord. There are only general statements on how the data from the two extreme ends of the nodal connection can used to estimate stress at desired locations along the intersecting tubular members intersect and subsequently weld fabricated to make the node that is subject to loading and fatigue damage. the dynamic motions and orientations from the Metocean conditions are compared to a “table of models” or “database of vibration signatures” to select the best matching model or signature; then, stresses are determined at a “plurality of intersecting tubular members.”

Attempting to determine the dynamic motions and stresses at the tubular intersection using only data from two endpoints is highly prone to error. Also, a very large number of predetermined models have to be generated by parameterizing all possible combinations of wind speed/direction, wave height/period/heading, current speed/heading/profile, etc. In addition, results from predetermined models are prone to error for complex vibration phenomena such as vortex induced vibration (VIV). Predictive VIV analysis software is currently unable to accurately predict stress and fatigue due to inline vibration, higher harmonics and traveling wave behavior. Therefore, such a method is prohibitive and likely to be inaccurate when applied to structure VIV.

In offshore structures, the intersections of tubular members are often called nodes. These nodes can sometimes be described by the geometric configuration and how many and how they interface with the tubular members (for example: a TKY Node). These welded intersections are subject to loads that may induce fatigue damage. It is important for operators to have the ability to verify performance of their structures during service conditions.

### SUMMARY OF EXAMPLE EMBODIMENTS

An example embodiment may include a subsea connection node comprising a first connector, a second connector, a body integrated with the first connector and the second connector; wherein at least a portion of the body is constructed with additive manufacturing, at least one encapsulating structure formed as part of the body, at least one sensor disposed within the at least one encapsulating structure.

The subsea connection node may include at least one additively manufactured encapsulating structure protruding from the inner surface of the first connector. It may include at least one sensor formed within the at least one additively manufactured encapsulating structure. The at least one sensor may be an accelerometer, a strain gauge, a thermocouple, a rate sensor, a piezo electric sensor, and/or an optical sensor.

An example embodiment may include a method for manufacturing a subsea node comprising building a subsea node body using an additive manufacturing process, forming at least one encapsulating structure into the subsea node, and installing at least one sensor into the encapsulating structure. The at least one sensor may be an accelerometer, a strain gauge, a thermocouple, a rate sensor, a piezo electric sensor, and/or an optical sensor. The method may include forming the encapsulating structure into an inner surface of the subsea node. The method may include forming the encapsulating structure into an outer surface of the subsea node.

### BRIEF DESCRIPTION OF THE DRAWINGS

For a thorough understanding of the present invention, reference is made to the following detailed description of the preferred embodiments, taken in conjunction with the accompanying drawings in which reference numbers designate like or similar elements throughout the several figures of the drawing. Briefly:

FIG. 1 shows an example embodiment of an embedded sensor in an additively manufacture component.

FIG. 2 shows an example embodiment of an embedded sensor in an additively manufacture component.

FIG. 3A shows a perspective view of a subsea node.

FIG. 3B shows a perspective cutaway view of a subsea node.

FIG. 3C shows a perspective view of an additively manufactured subsea node with structural support.

FIG. 3D shows a perspective cutaway view of an additively manufactured subsea node with embedded sensors.

FIG. 4A shows a perspective cutaway view of an additively manufactured subsea node with embedded sensors.

FIG. 4B shows a perspective cutaway view of an additively manufactured subsea node with embedded sensors.

FIG. 5A shows a side view of an additively manufactured subsea node with an embedded sensor.

FIG. 5B shows a detailed cutaway view of an additively manufactured subsea node with an internal embedded sensor.

FIG. 6A shows a perspective cutaway view of an additively manufactured subsea node with embedded sensors.

FIG. 6B shows a detailed cutaway view of an additively manufactured subsea node with an external embedded sensor.

### DETAILED DESCRIPTION OF EXAMPLES OF THE INVENTION

In the following description, certain terms have been used for brevity, clarity, and examples. No unnecessary limitations are to be implied therefrom and such terms are used for descriptive purposes only and are intended to be broadly construed. The different apparatus, systems and method steps described herein may be used alone or in combination with other apparatus, systems and method steps. It is to be expected that various equivalents, alternatives, and modifications are possible within the scope of the appended claims.

Additive manufacturing is a revolutionary technology process that is enabling the creation of components that traditionally have not been able to have been manufactured by building up a structure layer by layer. Due to this process of layer-by-layer buildup of a component access to the inside of a component is now achievable where with subtractive manufacturing access was not possible. With this new access to the internal areas of an additively manufactured component sensors can be placed within layers of a component while it is being additively manufactured.

Components used in critical applications have costly implications when failure occurs or when the components are exposed to conditions other then what they were designed or intended for. Therefore, it is desirable to have the ability to monitor the condition of these critical components with sensors that can relay information about the component to an observer. Once a component is manufactured, typical sensors are limited in the locations that they can monitor a component due to accessibility. Sometimes the most desirable sensor measurement location is in an area that in not accessible. For example, near internal cavities or features such as the inner diameter of a pressure vessel or structural member. Placing sensors within components in inaccessible areas is possible if the sensors are placed during the manufacturing process. For example, during additive manufacturing where a component is built up layer by layer a sensor can be placed while the desired sensor location is accessible before the component is completely manufactured.

For metallic additive manufacturing, placing sensors during the printing process can be challenging due to the high temperatures involved. Sensors with a desirable high level of fidelity and sensitivity are often delicate and unable to withstand the high temperatures experienced during a metallic additive manufacturing process. The present work presents a solution to this by utilizing either high temperature sensors or utilizing thermal insulating layers. Sensors also cannot typically withstand exposure to environmental conditions such as rain, water, humidity, erosion, wind, etc. and can present false readings from external influences. Having the sensors embedded within the component and sealed with in the body solves this challenge.

Types of sensors that may be considered include strain gages, thermocouples, acoustic emission sensors, displacement transducers, ultrasonic measurement devices, pressure transducers, accelerometers, and optical sensors. The sensor may communicate via hard wired, wireless, induction, or collect data autonomously without external communication. The sensor may be powered with an external source or include an internal battery. The sensor may be passive and only respond when excited by a magnetic field.

The sensors are placed in key locations as determined by analysis of the component they installed on. Using advanced analysis and simulation techniques to predetermine key sensor placement locations is a unique and novel approach. These sensors will be placed such that only a reduced number of sensors can be used to feed data into a digital twin model of the component to make accurate assumptions about the performance of the entire component without the need to install sensors around the entire component.

An example embodiment may include Optimized Geometrical Configuration Joint Design for reduced material usage and improved fatigue resistance.

The Geometrical Configuration Joint may be designed such that sensors can be installed onto it for more accurate readings. For example, pockets or cut-outs maybe be included to allow for proper sensor placement.

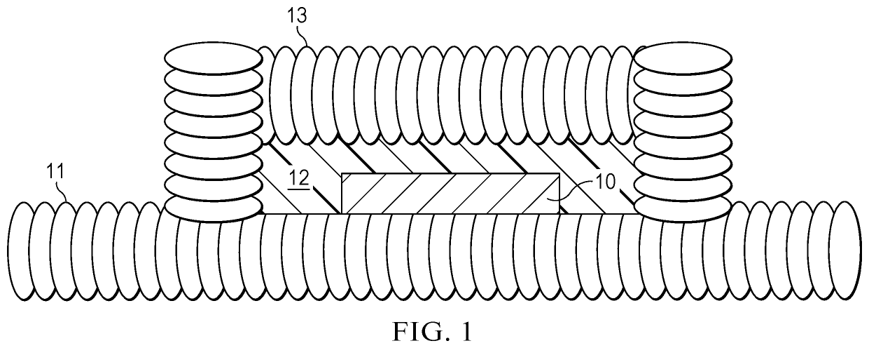

An example embodiment is shown in FIG. 1 of an embedded sensor 10 placed on an additive substrate 11, surrounded by a protective layer 12, which may include waterproof or shock proof packaging, and then further surrounded by optional additive encapsulating layers 13.

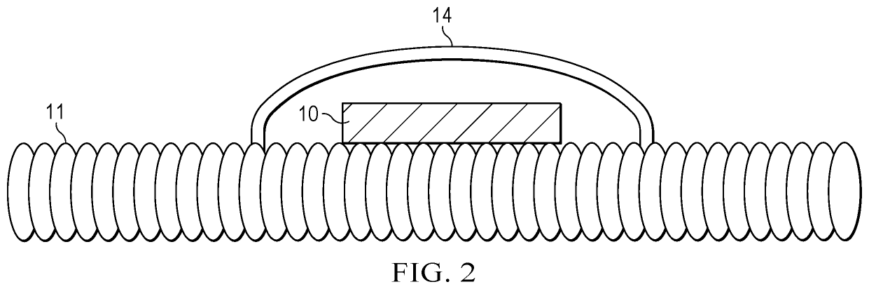

An example embodiment is shown in FIG. 2 of an embedded sensor 10 placed on an additive substrate 11, surrounded by an encapsulating structure 14.

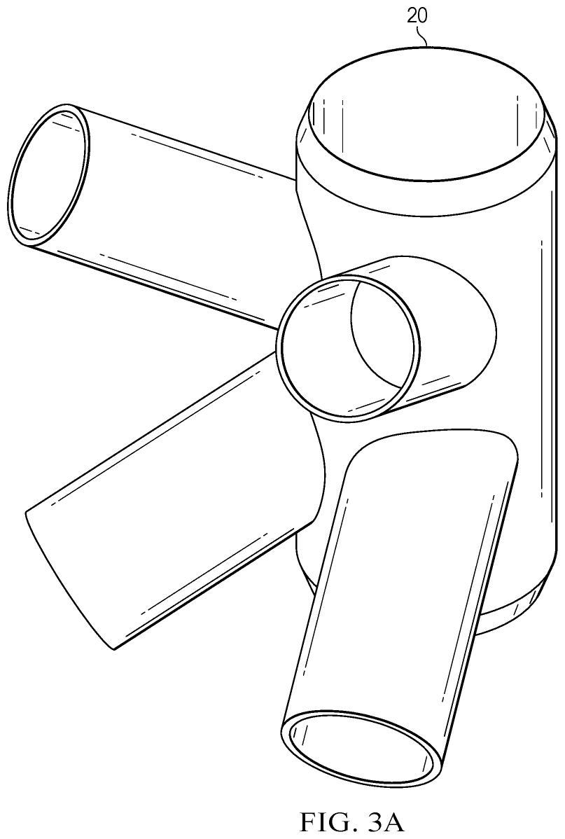

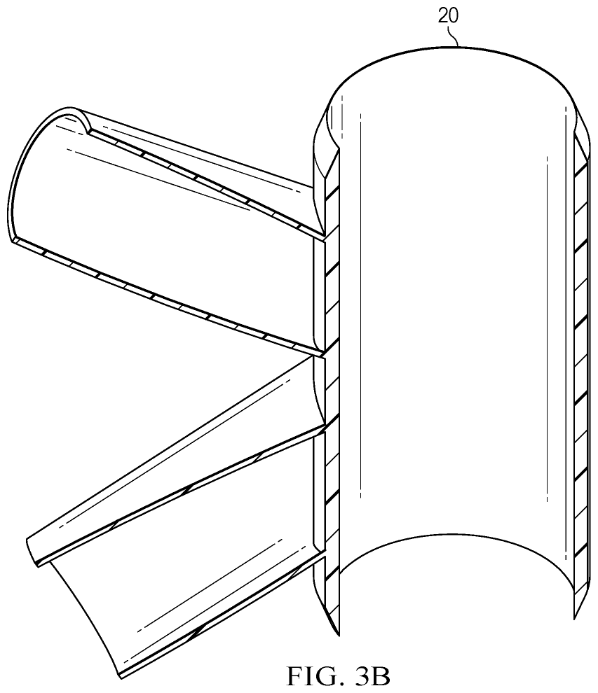

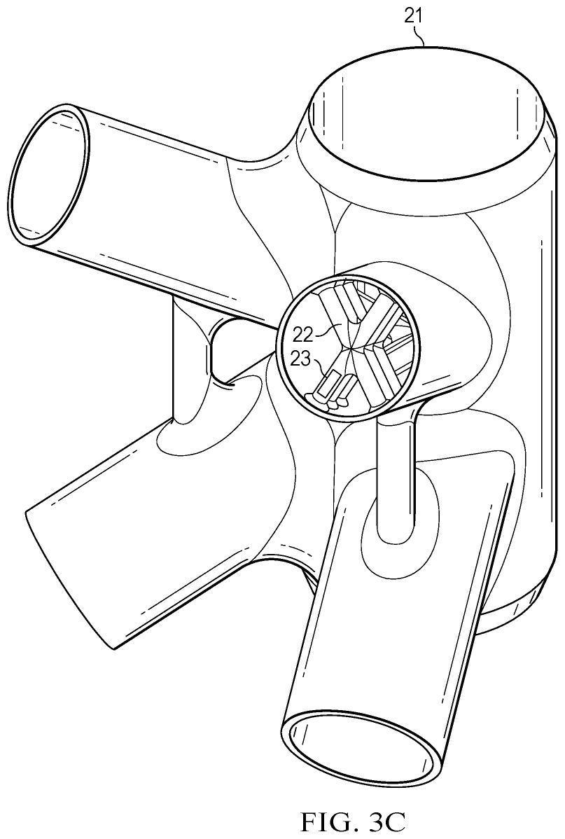

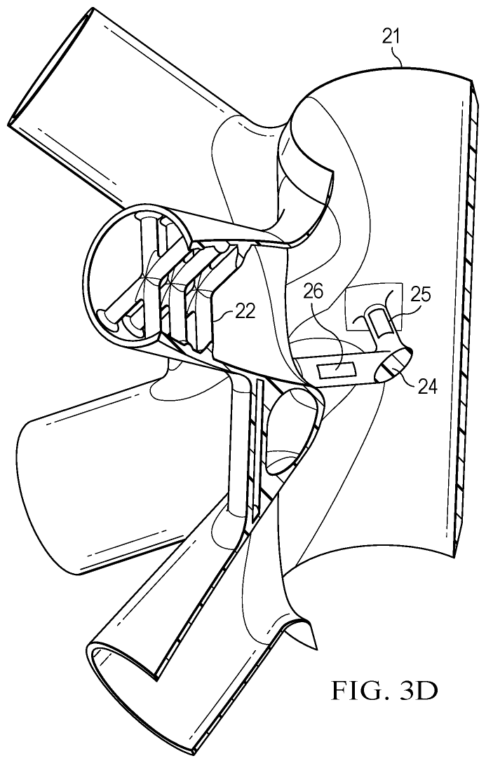

An example shown in FIGS. 3A and 3B shows a traditionally manufactured connection node 20 in both a perspective and cross-sectioned view. An example embodiment in the perspective view of FIG. 3C and the cross-sectioned perspective view of FIG. 3D shows an additively manufactured connection node 21, such as a jacket node, having encapsulating structures 22 that contain sensors 23 therein. A plurality of encapsulating structures 22 can each house one or more sensors 23 for detecting strain, accelerations, temperature, and vibrations. A plurality of encapsulating structures 22 also allows for a plurality of sensors should one fail or get damaged. The main support of connection node 21 may include another encapsulating structure 24, which can include an encapsulated sensor 25 and/or an exterior mounted sensor 26.

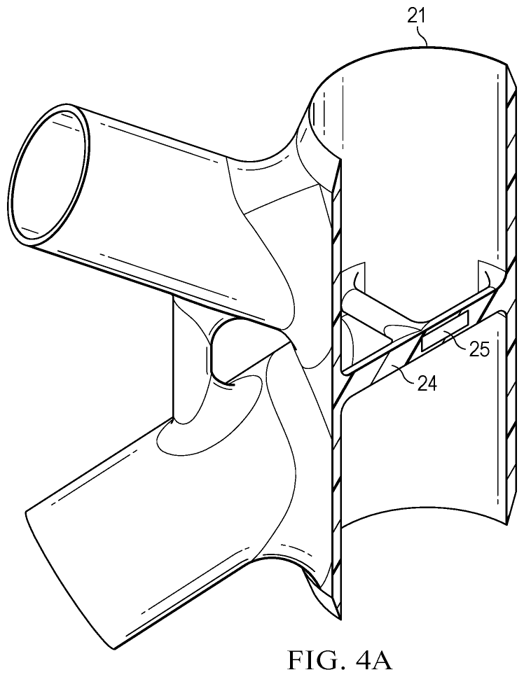

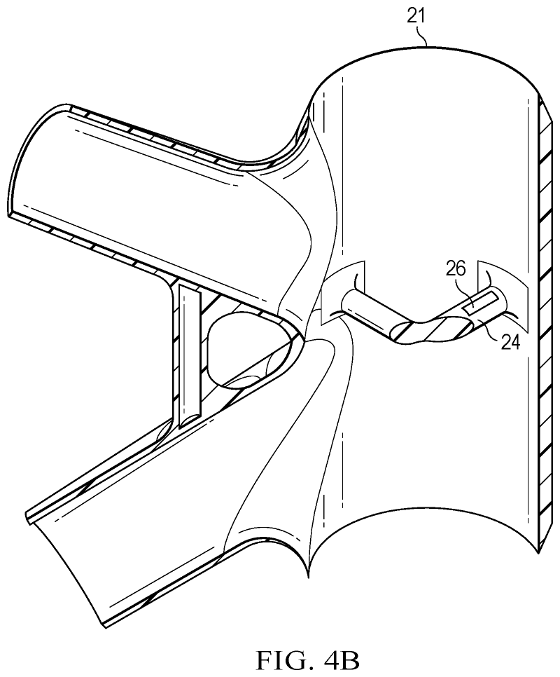

An example embodiment in the sectioned perspective view of FIG. 4A and the sectioned perspective view of FIG. 4B shows an additively manufactured connection node 21 having encapsulating structures 24 that can include encapsulated sensor 25 and/or an exterior mounted sensor 26.

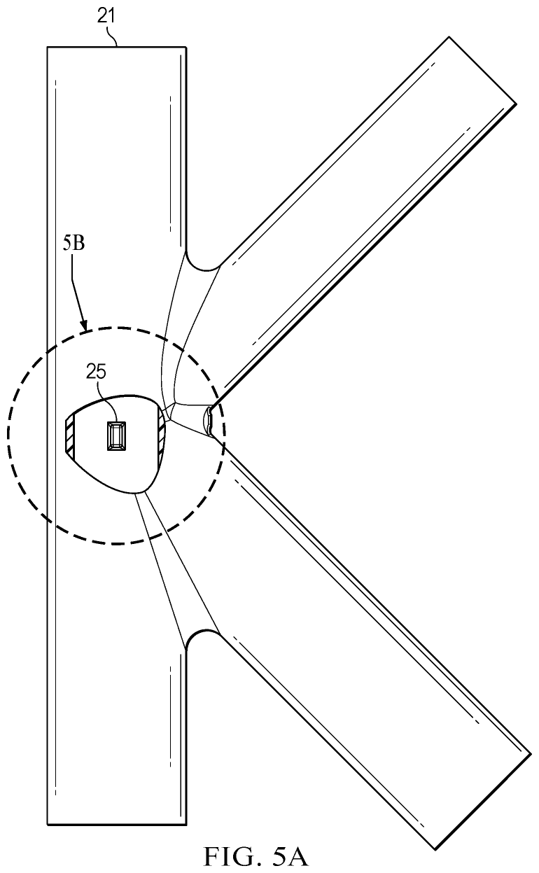

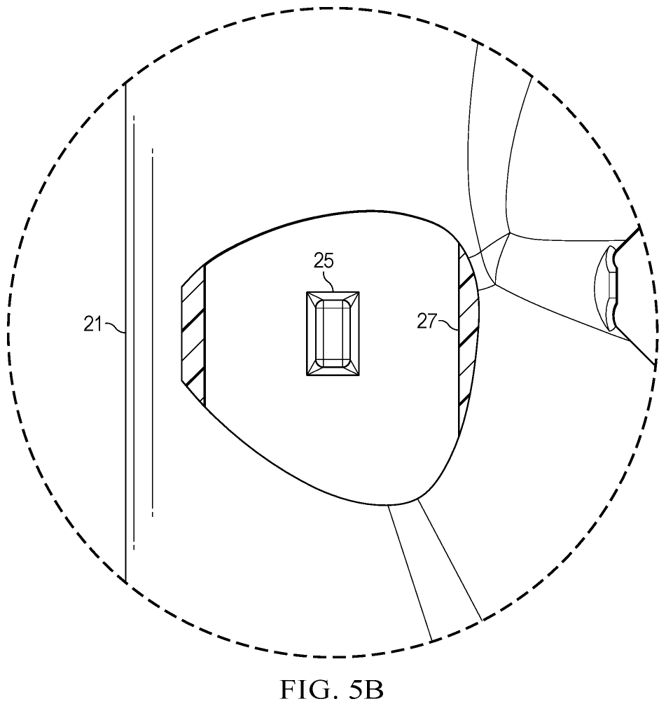

An example embodiment is shown in FIG. 5A with a close up sectional in FIG. 5B. The additively manufactured connection node 21 has an encapsulating structure 25 mounted to its inside surface 27. The encapsulating structure 25 can be one or more structures and each structure can contain one or more sensors of various types.

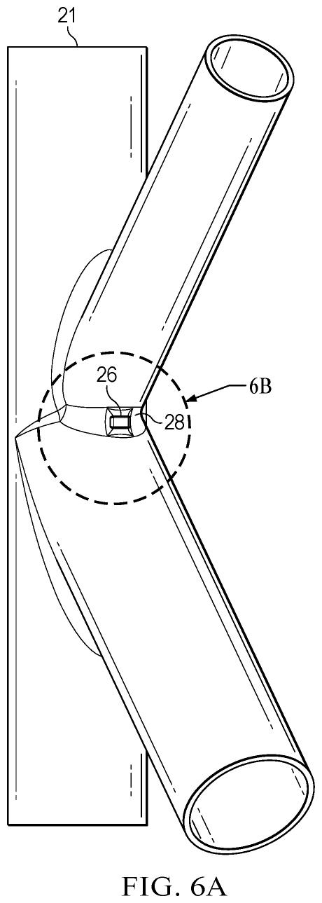

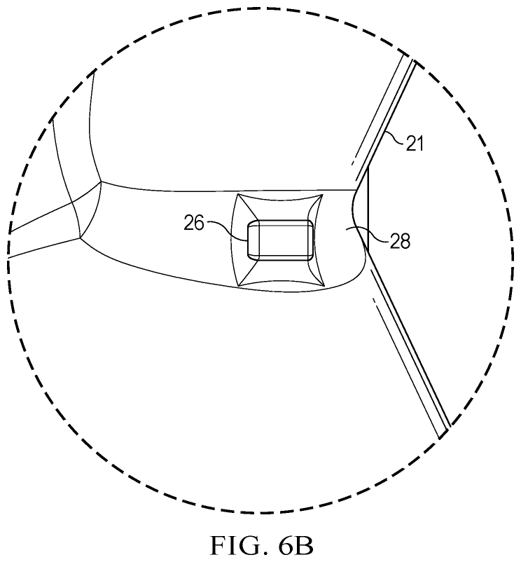

An example embodiment is shown in FIG. 6A with a close up sectional in FIG. 6B. The additively manufactured connection node 21 has an encapsulating structure 26 formed into the exterior surface 28. The encapsulating structure 26 can be one or more structures and each structure can contain one or more sensors of various types.

The connection node does not need to be limited by geometry and can be any connection that sees stress levels that are of concern. The encapsulating structure can be open, such as a pocket design, where a sensor cassette can be inserted or removed from the pocket. Furthermore, the encapsulating structure can be designed to be gradual so as to minimize stress risers in the connection node. The sensor can have direct communication with a monitoring system or intermittent communication with data collection device, such as a ROV that interfaces with the sensor at desired intervals.

Although the invention has been described in terms of embodiments which are set forth in detail, it should be understood that this is by illustration only and that the invention is not necessarily limited thereto. For example, terms such as upper and lower or top and bottom can be substituted with uphole and downhole, respectfully. Top and bottom could be left and right, respectively. Uphole and downhole could be shown in figures as left and right, respectively, or top and bottom, respectively. The alternative embodiments and operating techniques will become apparent to those of ordinary skill in the art in view of the present disclosure. Accordingly, modifications of the invention are contemplated which may be made without departing from the spirit of the claimed invention.

What is claimed is:

1. A subsea connection node comprising:
a first tubular connector;
a second tubular connector; and some case more than two tubular connector a body integrated with the first tubular connector and the second connector; wherein at least a portion of the body is constructed with additive manufacturing;
at least one encapsulating structure formed as part of the body;
at least one sensor disposed within the at least one encapsulating structure.

2. The subsea connection node of claim 1, further comprising at least one additively manufactured encapsulating structure protruding from the inner surface of the first connector.

3. The subsea connection node of claim 2, further comprising at least one sensor formed within the at least one additively manufactured encapsulating structure.

4. The subsea connection node of claim 1, wherein the at least one sensor is an accelerometer.

5. The subsea connection node of claim 1, wherein the at least one sensor is a strain gauge.

6. The subsea connection node of claim 1, wherein the at least one sensor is a thermocouple.

7. The subsea connection node of claim 1, wherein the at least one sensor is a rate sensor.

8. The subsea connection node of claim 1, wherein the at least one sensor is a piezo electric sensor.

9. The subsea connection node of claim 1, wherein the at least one sensor is an optical sensor.

10. A method for manufacturing a subsea node comprising:
building a subsea node body using an additive manufacturing process;
forming at least one encapsulating structure into the subsea node; and
installing at least one sensor into the encapsulating structure.

11. The method for manufacturing a subsea node of claim 10, wherein the at least one sensor is an accelerometer.

12. The method for manufacturing a subsea node of claim 10, wherein the at least one sensor is a strain gauge.

13. The method for manufacturing a subsea node of claim 10, wherein the at least one sensor is a thermocouple.

14. The method for manufacturing a subsea node of claim 10, wherein the at least one sensor is a rate sensor.

15. The method for manufacturing a subsea node of claim 10, wherein the at least one sensor is a piezo electric sensor.

16. The method for manufacturing a subsea node of claim 10, wherein the at least one sensor is an optical sensor.

17. The method for manufacturing a subsea node of claim 10, further comprising forming the encapsulating structure into an inner surface of the subsea node.

18. The method for manufacturing a subsea node of claim 10, further comprising forming the encapsulating structure into an outer surface of the subsea node.
